(19) United States
(12) Patent Application Publication
(10) Pub. No.: US 2019/0123057 A1
(43) Pub. Date: Apr. 25, 2019

(54) NOVEL NON-VOLATILE MEMORY AND METHOD FOR MANUFACTURING THE SAME

(71) Applicant: Chengdu Analog Circuit Technology Inc, Chengdu (CN)

(72) Inventors: HONGSONG NI, CHENGDU (CN); MING WANG, CHENGDU (CN)

(73) Assignee: Cheungdu Analog Circuit Technology Inc

(21) Appl. No.: 16/199,201

(22) Filed: Nov. 25, 2018

Related U.S. Application Data
(63) Continuation of application No. PCT/CN2017/107594, filed on Oct. 25, 2017.

(51) Int. Cl. H01L 27/11524; H01L 27/11529; H01L 29/66

(52) U.S. Cl. CPC H01L 27/11524; H01L 29/66825; H01L 27/11529

(57) ABSTRACT

The present invention relates to a novel non-volatile memory and a method for manufacturing the same, wherein the novel non-volatile memory includes a selection transistor and a memory transistor, the selection transistor includes a gate oxide layer and a first logic gate. A non-volatile memory with another structure includes a memory transistor, the memory transistor includes a tunneling dielectric layer, a floating gate, a second inter-gate dielectric layer and a second logic gate arranged in sequence. The memory of the present invention, through the traditional control gate that is replaced by a logic gate, makes the manufacturing process of the memory simpler, and also reduces the number of reticles used, thereby reducing the manufacturing cost.

### CROSS-REFERENCE TO RELATED APPLICATIONS

This application is a continuation of International Patent Application No. PCT/CN2017/107594 with a filing date of Oct. 25, 2017, designating the United States, now pending. The content of the aforementioned applications, including any intervening amendments thereto, are incorporated herein by reference.

### TECHNICAL FIELD

The present invention relates to the field of memory technology, and in particular to a novel non-volatile memory and a method for manufacturing the same.

### TECHNICAL BACKGROUND

A non-volatile memory, also known as the non-volatile memory, is referred to as NVM, which means that the information stored in the memory can still exist for a long time after power is turned off, and is not easily lost. A two-transistor non-volatile memory refers to a memory including two transistors, one is a selection transistor functioning as selection and the other is a memory transistor functioning as storage. At present, the high-performance two-transistor memory has the disadvantages of a complicated process, and a logic-based process thereof requiring an additional dozen or more photomasks, and a high cost.

### SUMMARY OF THE PRESENT INVENTION

An object of the present invention is to improve the above-mentioned deficiencies in the prior art and provide a novel non-volatile memory and a method for manufacturing the same.

In order to achieve the above object, the embodiments of the present invention provide the following technical solutions:

A novel non-volatile memory comprises a selection transistor and a memory transistor, the selection transistor comprises a gate oxide layer and a first logic gate. Furthermore, the gate oxide layer is a gate oxide of a first inter-gate dielectric layer or a peripheral logic device.

In the above novel non-volatile memory, the selection transistor is composed of the gate oxide layer and a first logic gate, and the process of forming the first logic gate is more simplified than the process of forming a control gate in the conventional selection transistor, thus making the manufacturing process of the entire memory is simpler, furthermore, the processes of stacking the conventional control gate and a floating gate and removing the inter-gate dielectric layer are omitted, which further simplifies the manufacturing process of the memory and reduces the number of photomasks used, the traditional ten or more photomasks are reduced to four photomasks, which in turn reduces the manufacturing cost of the memory. In addition, by adjusting the thickness of the first inter-gate dielectric layer, or by using the gate oxide of the peripheral logic device as the gate oxide layer, a read rate can still be improved and a data retention capability is excellent.

Furthermore, in the above novel non-volatile memory, the memory transistor comprises a tunneling dielectric layer, the floating gate, a second inter-gate dielectric layer and a second logic gate arranged in sequence. Replacing the conventional control gate with the second logic gate can further simplify the manufacturing process of the entire memory and reduce manufacturing complexity.

Furthermore, in the above novel non-volatile memory, the second inter-gate dielectric layer extends from the top surface of the floating gate toward the sidewall thereof, surrounds the floating gate, and takes the tunneling electrical layer as the bottom, the floating gate is wrapped up by the second inter-gate dielectric layer and the tunneling dielectric layer; and the second logic gate surrounds part or all of the second inter-gate dielectric layer.

Compared with a conventional stacked type structure, the present invention increases the contact area between the second logic gate and the second inter-gate dielectric layer by an enclosing manner, that is, increases the capacitance of the second logic gate to the floating gate, thereby increasing the coupling ratio of the second logic gate to the floating gate.

The embodiments of the present invention further provide a novel non-volatile memory of another structure, comprising the memory transistor, the memory transistor comprises the tunneling dielectric layer, the floating gate, the second inter-gate dielectric layer, and the second logic gate arranged in sequence. By replacing the conventional control gate with the second logic gate, the manufacturing process flow of the memory can be simplified.

Furthermore, in the above novel non-volatile memory, the second inter-gate dielectric layer extends from the top surface of the floating gate toward the sidewall thereof, surrounds the floating gate, and takes the tunneling electrical layer as the bottom, the floating gate is wrapped up by the second inter-gate dielectric layer and the tunneling dielectric layer; and the second logic gate surrounds part or all of the second inter-gate dielectric layer.

Furthermore, the second logic gate surrounds a top surface and two sidewalls of the second inter-gate dielectric layer.

The embodiments of the present invention provides a method for manufacturing a novel non-volatile memory at the same time, the method comprising the steps of:

forming the tunneling dielectric layer in a memory transistor structure on a substrate after an isolation process of a shallow trench;

depositing a floating gate material;

forming a floating gate in the memory transistor structure via an etching process by means of a photomask;

forming a first inter-gate dielectric layer in the selection transistor and the second inter-gate dielectric layer in the memory transistor structure via a thermal oxidation method or a thin film deposition method; and

forming a first logic gate in the selection transistor and a second logic gate in the memory transistor structure via the etching process by means of the photomask.

The memory is manufactured by the above method, the process is simple, the traditional memory manufacturing process flow is simplified, the use of the photomask is reduced, and the cost is saved. In addition, by a manner of forming the floating gate via the etching process by means of the photomask, the thickness of the floating gate can be made larger, and the memory performance of the memory is better.

In another embodiment, the step of forming the floating gate in the memory transistor structure via the etching process by means of the photomask is replaced by the following steps: using the height difference between a shallow trench isolation STI and an active region, and using the photomask to form the floating gate in the memory transistor structure via the etching process again after a chemical mechanical polishing process. Using this method to form the floating gate can avoid some of the limitations of the process rules, so that the memory cell can be made smaller.

In a further optimized solution, in the above method, in the step of forming the second inter-gate dielectric layer via the thermal oxidation method or the thin film deposition method, the second inter-gate dielectric layer extends from the top surface of the floating gate toward the sidewall thereof, surrounds the floating gate and takes the tunneling electrical layer as the bottom, the floating gate is wrapped up by the second inter-gate dielectric layer and the tunnel dielectric layer; in the step of forming the second logic gate via the etching process by means of the photomask, the second logic gate surrounds part or all of the second inter-gate dielectric layer.

Compared with the prior art, the novel non-volatile memory of the present invention and the method for manufacturing the same have the beneficial effects:
(1) The control gates of the selection transistor and the storage transistor are replaced by the logic gates, and the process of forming the logic gate is more simplified than the process of forming the control gate in the conventional selection transistor, thereby making the manufacturing process of the entire memory simpler, and additionally, the processes of stacking the conventional control gate and the floating gate and removing the inter-gate dielectric layer are omitted, so that the manufacturing process of the memory is further simplified.
(2) The processes of stacking the traditional control gate and the floating gate and removing the inter-gate dielectric layer are omitted, and the number of the photomasks used is reduced, the traditional ten or more photomasks are reduced to four photomasks, thereby further reducing the cost of manufacturing the memory.
(3) In the selection transistor, by adjusting the thickness of the first inter-gate dielectric layer, or by using the gate oxide of the peripheral logic device as the gate oxide layer, a read rate can be improved and a data retention capability is excellent.
(4) The manners that the second inter-gate dielectric layer surrounds the floating gate and the second logic gate surrounds the second inter-gate dielectric layer can increase the contact area between the second logic gate and the second inter-gate dielectric layer, that is, increases the capacitance of the second logic gate to the floating gate, thereby increasing the coupling ratio of the second logic gate to the floating gate.
(5) The method for forming the floating gate via the etching process by means of the photomask can make the thickness of the floating gate larger, and the storage performance of the memory is better.
(6) The method for using the height difference between the shallow trench isolation STI and the active region and forming the floating gate via the etching process by means of the photomask after the chemical mechanical polishing process can avoid the limitation of some process rules, so that the memory cell can be made smaller.
(7) In addition, since all memory-related processes are completed before the process of the peripheral logic device, that is, the memory process does not affect the logic manufacturing process, therefore, the memory of the present invention is well compatible with the logic device.

### BRIEF DESCRIPTION OF THE DRAWINGS

In order to more clearly illustrate the technical solutions of the embodiments of the present invention, the drawings to be used in the embodiments will be briefly described below, it should be understood that the following drawings show only certain embodiments of the present invention, and therefore, it should be seen as a limitation on the scope, and the person skilled in the art can obtain other related drawings according to the drawings without any creative work.

FIG. 1 is a top plan view of a novel non-volatile memory provided by an embodiment of the present invention.

FIG. 2 is a cross-sectional view of FIG. 1 taken along line A-A.

FIG. 3 is a cross-sectional view of FIG. 1 taken along line B-B.

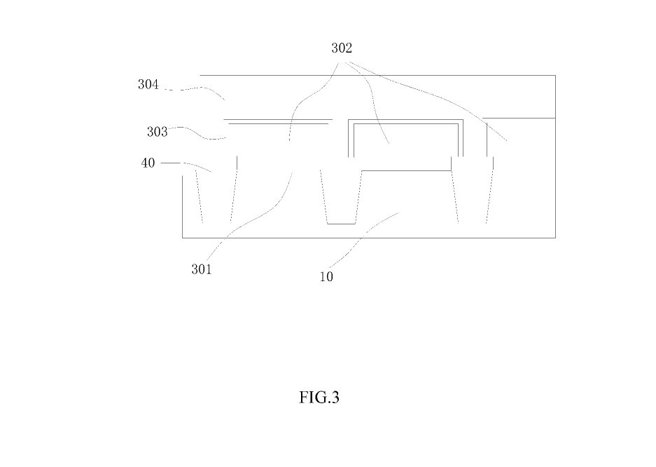

FIG. 4 is a diagram of a second logic gate surrounding the top surface and one sidewall of a second inter-gate dielectric layer.

FIG. 5 is a flow chart of a manufacturing process of a novel non-volatile memory provided by an embodiment of the present invention.

### THE DESCRIPTION OF REFERENCE SIGNS IN FIGURES

Substrate 10; selection transistor 20; memory transistor 30; shallow trench isolation STI 40; P-type doped region 101; N-type well 102; gate oxide layer 201; first logic gate 202; tunneling dielectric layer 301; floating gate 302; second inter-gate dielectric layer 303; second logic gate 304.

### DETAILED DESCRIPTION

The technical solutions in the embodiments of the present invention are clearly and completely described in the following with reference to the accompanying drawings in the embodiments of the present invention, it is obvious that the described embodiments are only a part of the embodiments of the present invention, but not all embodiments, the components of the embodiments of the invention, which are generally described and illustrated in the figures herein, may be arranged and designed in various different configurations. Therefore, the following detailed description of the embodiments of the present invention in the figures is not designed to limit the scope of the present invention required to be protected, but merely shows the selected embodiments of the present invention. All other embodiments obtained by the person skilled in the art based on the embodiments of the present invention without creative efforts are within the scope of the present invention.

It should be noted that in the description of the present invention, the terms “first”, “second”, etc. are used only to distinguish the description, and are not to be construed as indicating or implying relative importance.

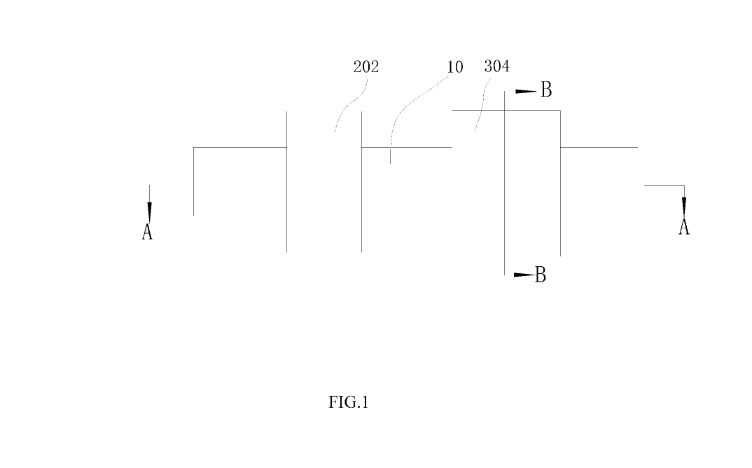

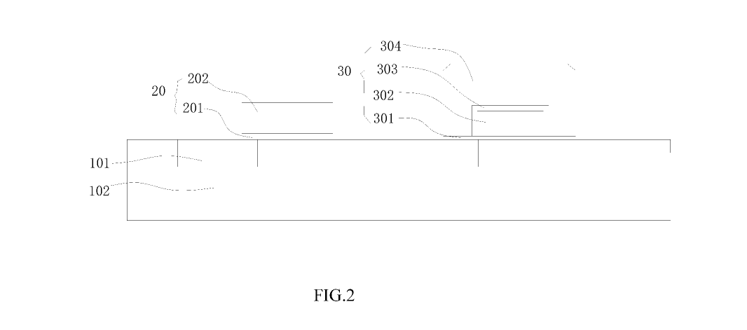

Referring to FIGS. 1-2, a novel non-volatile memory provided in the first embodiment of the present invention comprises a selection transistor 20 and a memory transistor 30, wherein the selection transistor 20 comprises a gate oxide layer 201 and a first logic gate 202, the gate oxide layer 201 can be a first inter-gate dielectric layer or a gate oxide of a peripheral logic device. The memory transistor 30 comprises a tunneling dielectric layer 301, a floating gate 302, a second inter-gate dielectric layer 303 and a second logic gate 304 arranged in sequence, the second inter-gate dielectric layer 303 can be an oxide or a nitrogen, for example, a silicon oxide.

In the above novel non-volatile memory, the control gates of the selection transistor 20 and the memory transistor 30 are replaced by the logic gate, and the process of forming the logic gate is more simplified than the process of forming the control gate, thus making the entire memory manufacturing process simpler. In addition, compared with the structure of the conventional selection transistor 20, that is, the control gate of the selection transistor 20 and the floating gate 302 are stacked together, and the inter-gate dielectric layer is removed, the manufacturing process of the selection transistor 20 in the present invention is omitted, in the present invention, from the process of manufacturing the selection transistor 20, the processes of stacking the control gate and the floating gate 302 and removing the inter-gate dielectric layer not only further simplify the manufacturing process of the selection transistor 20, but also reduce the number of the photomasks used, the conventional ten or more photomasks are reduced to four photomasks, which in turn reduces the manufacturing cost of the memory and simplifies the structure of the selection transistor 20. In addition, by adjusting the thickness of the first inter-gate dielectric layer, or by using the gate oxide of the peripheral logic device as the gate oxide layer 201, the read rate can be improved and the data retention capability is excellent.

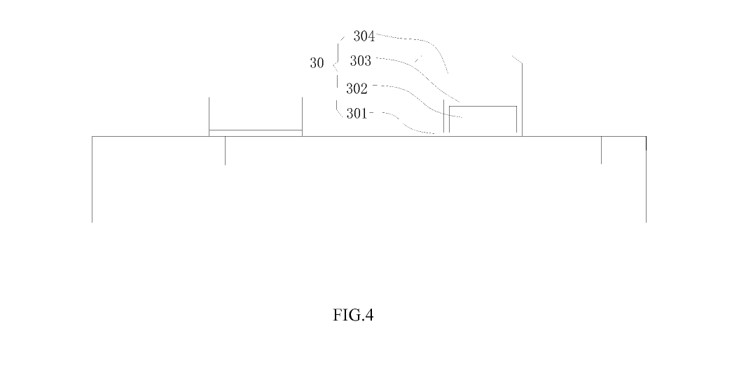

In a further optimized solution, for the memory transistor 30, the second inter-gate dielectric layer 303 extends from the top surface of the floating gate 302 toward the sidewall thereof, surrounds the floating gate 302, and takes the tunneling dielectric layer 301 as the bottom, the floating gate 302 is wrapped up by the second inter-gate dielectric layer 303 and the tunneling dielectric layer 301; the second logic gate 304 surrounds part or all of the second inter-gate dielectric layer 303. For example, FIG. 2 shows that the second logic gate 304 surrounds the top surface and the two sidewalls of the second inter-gate dielectric layer 303, and FIG. 4 shows that the second logic gate 304 surrounds the top surface and one sidewall of the second inter-gate dielectric layer 303. As another embodiment, the second logic gate 304 can only surround all or part of the top surface of the second inter-gate dielectric layer 303; or the second logic gate 304 can surround one part of the top surface or one sidewall or one part of sidewall of the second gate dielectric layer 303. All of the embodiments that can be implemented are not listed here. Surrounding the floating gate 302 can increase the contact area between the second logic gate 304 and the second inter-gate dielectric layer 303, that is, increase the capacitance of the second logic gate 304 to the floating gate 302, thereby increasing the coupling ratio of the two logic gates 304 to the floating gate 302.

Compared with the conventional two-transistor type non-volatile memory, in the above-described first embodiment, the structures of the selection transistor 20 and the memory transistor 30 are both improved, but it is easy to understand that, in a feasible solution, only the structure of the selection transistor 20 can be improved, that is, the selection transistor 20 comprises the gate oxide layer 201 and the first logic gate 202, or only the structure of the memory transistor 30 can be improved, that is, the conventional control gate is replaced with the second logic gate 304. Both of these feasible solutions can solve the problem of poor compatibility of traditional non-volatile memory and the logic device. In addition, the improvement of the structure of the memory transistor 30 can also be applied to a single-transistor floating volatile memory, that is, the single-transistor floating volatile memory comprises the memory transistor 30, the memory transistor 30 comprises the tunneling dielectric layer 301, the floating gate 302, the second inter-gate dielectric layer 303, and the second logic gate 304 arranged in sequence.

As shown in FIG. 1, the structural improvement of the conventional non-volatile memory of the present invention can be applied to a PMOS device, that is, the selection transistor 20 and the memory transistor 30 are both arranged on the substrate 10, a P-type doped region 101 and an N-type well 102 are arranged on the substrate 10; the structural improvement thereof is also applicable to an NMOS device, that is, the selection transistor and the storage transistor are both arranged on the substrate, and the substrate is provided thereon with an N-type doped region and a P-type well.

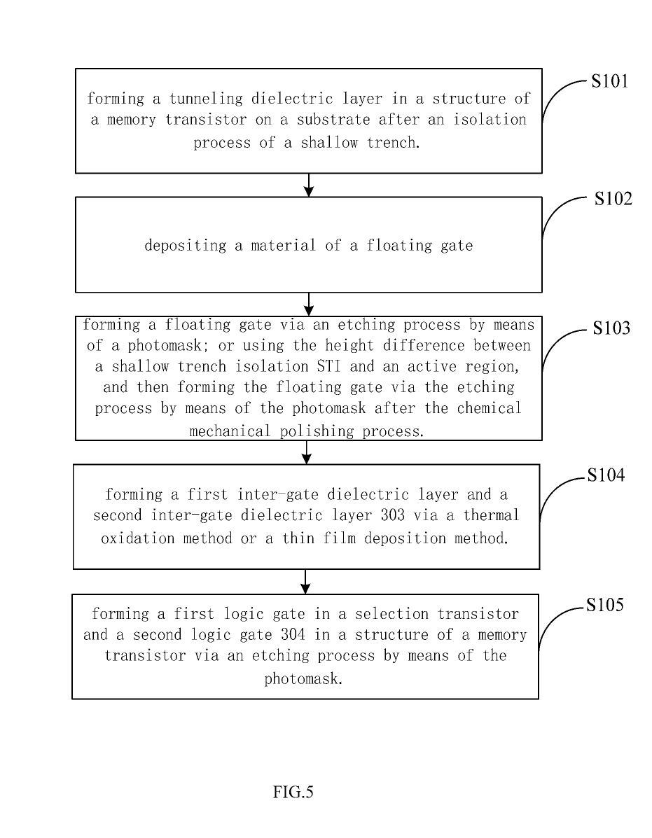

Referring to FIG. 5, a method for manufacturing a novel non-volatile memory provided by a second embodiment of the present invention comprises the following steps:

S101, forming the tunneling dielectric layer in the structure of the memory transistor 30 on the substrate 10, after the isolation process of the shallow trench.

S102, depositing the material of the floating gate 302.

S103, forming the floating gate 302 in the structure of the memory transistor 30 via the etching process by means of the photomask; or using the height difference between a shallow trench isolation STI and an active region, and then forming the floating gate 302 in the structure of the memory transistor 30 via the etching process by means of the photomask after the chemical mechanical polishing process. The thickness of the floating gate 302 can be made thick by the method for forming the floating gate 302 via the etching process by means of the photomask, thereby increasing the storage capacity; however, a method for grinding and etching can avoid the limitation of a plurality of process rules, a storage unit can be made smaller to adapt to the trend of product miniaturization.

S104, forming a first inter-gate dielectric layer in the selection transistor 20 and a second inter-gate dielectric layer 303 in the structure of the memory transistor 30 via a thermal oxidation method or a thin film deposition method. In this step, in order to enhance the coupling performance of the memory, during the process of forming the second inter-gate dielectric layer 303, the second inter-gate dielectric layer 303 can extend from the top surface of the floating gate 302 toward the sidewall thereof, surrounds the floating gate 302 and takes the tunneling dielectric layer 301 as the bottom, the floating gate 302 is wrapped up by the second inter-gate dielectric layer 303 and the tunnel dielectric layer 301.

S105, forming a first logic gate 202 in the selection transistor 20 and a second logic gate 304 in the structure of the memory transistor 30 via the etching process by means of the photomask. In this step, in order to enhance the coupling performance of the memory, during the process of forming the second logic gate 304, the second logic gate 304 can surround part or all of the second inter-gate dielectric layer 303.

The above is only the specific embodiment of the present invention, but the scope of the present invention is not limited thereto, and any person skilled in the art can easily think of changes or substitutions within the technical scope of the present invention, which should be covered by the scope of the present invention.

We claim:

1. A novel non-volatile memory, characterized by comprising a selection transistor and a memory transistor, the selection transistor comprising a gate oxide layer and a first logic gate.

2. The novel non-volatile memory of claim 1, characterized in that the gate oxide layer is a gate oxide of a first inter-gate dielectric layer or a peripheral logic device.

3. The novel non-volatile memory of claim 1, characterized in that the memory transistor comprises a tunneling dielectric layer, a floating gate, a second inter-gate dielectric layer and a second logic gate arranged in sequence.

4. The novel non-volatile memory according to claim 3, characterized in that the second inter-gate dielectric layer extends from the top surface of the floating gate toward the sidewall thereof, surrounds the floating gate, and takes the tunneling electrical layer as the bottom, the floating gate is wrapped up by a second inter-gate dielectric layer and a tunneling dielectric layer; and the second logic gate surrounds part or all of the second inter-gate dielectric layer.

5. The novel non-volatile memory of claim 4, characterized in that the second logic gate surrounds a top surface and two sidewalls of the second inter-gate dielectric layer.

6. The novel non-volatile memory of claim 3, characterized in that the second inter-gate dielectric layer is an oxide or a nitride.

7. The novel non-volatile memory of claim 1, characterized in that the select transistor and the memory transistor are both arranged on the substrate, and the P-type doped region and the N-type well are arranged on the substrate.

8. The novel non-volatile memory of claim 1, characterized in that the selection transistor and the memory transistor are both arranged on a substrate, and the substrate is provided thereon with an N-type doped region and a P-type well.

9. A novel non-volatile memory, comprising a memory transistor, characterized in that the memory transistor comprises a tunneling dielectric layer, a floating gate, a second inter-gate dielectric layer and a second logic gate arranged in sequence.

10. The novel non-volatile memory according to claim 9, characterized in that the second inter-gate dielectric layer extends from the top surface of the floating gate toward the sidewall thereof, surrounds the floating gate, and takes the tunneling electrical layer as the bottom, the floating gate is wrapped up by the second inter-gate dielectric layer and the tunneling dielectric layer; and the second logic gate surrounds part or all of the second inter-gate dielectric layer.

11. The novel non-volatile memory of claim 10, characterized in that the second logic gate surrounds a top surface and two sidewalls of the second inter-gate dielectric layer.

12. A novel non-volatile memory device according to claim 9, characterized in that the second inter-gate dielectric layer is an oxide or a nitride.

13. The novel non-volatile memory according to claim 1, characterized in that the memory transistor is arranged on the substrate, and the substrate is provided thereon with an N-type doped region and a P-type well, or the substrate is provided thereon with a P-type doped region and an N-type well.

14. A method for manufacturing a novel non-volatile memory, characterized by comprising the steps of:
forming a tunneling dielectric layer in a memory transistor structure on a substrate after an isolation process of a shallow trench;
depositing a floating gate material;
forming a floating gate in the memory transistor structure via an etching process by means of a photomask;
forming a first inter-gate dielectric layer in a selection transistor and a second inter-gate dielectric layer in the memory transistor structure via a thermal oxidation method or a thin film deposition method; and
forming a first logic gate in the selection transistor and a second logic gate in the memory transistor structure via the etching process by means of the photomask.

15. The method for claim 14, characterized in that the step of forming the floating gate in the memory transistor structure via the etching process by means of the photomask is replaced by the following steps:
using the height difference between an shallow trench isolation STI and an active region, and forming the floating gate in the memory transistor structure via the etching process by means of the photomask again after a chemical mechanical polishing process.

16. The method according to claim 14, characterized in that in the step of forming the second inter-gate dielectric layer via the thermal oxidation method or the thin film deposition method, the second inter-gate dielectric layer extends from the top surface of the floating gate toward the sidewall thereof, surrounds the floating gate and takes the tunneling electrical layer as the bottom, the floating gate is wrapped up by the second inter-gate dielectric layer and the tunnel dielectric layer; in the step of forming the second logic gate via the etching process by means of the photomask, the second logic gate surrounds part or all of the second inter-gate dielectric layer.
